(19) United States
(12) Patent Application Publication
(10) Pub. No.: US 2014/0124758 A1
(43) Pub. Date: May 8, 2014

(54) ORGANIC LIGHT EMITTING DIODE DISPLAY AND MANUFACTURING METHOD THEREOF

(71) Applicant: SAMSUNG DISPLAY CO., LTD., Yongin-si (KR)

(72) Inventors: Byeong-Wook YOO, Yongin-City (KR); Sang-Woo PYO, Yongin-City (KR); Ha-Jin SONG, Yongin-City (KR); Hyo-Yeon KIM, Yongin-City (KR); Hye-Yeon SHIM, Yongin-City (KR); Ji-Young KWON, Yongin-City (KR)

(73) Assignee: SAMSUNG DISPLAY CO., LTD., Yongin-City (KR)

(21) Appl. No.: 14/025,076

(22) Filed: Sep. 12, 2013

(30) Foreign Application Priority Data
Nov. 5, 2012 (KR) 10-2012-0124314

(51) Int. Cl. H01L 51/50; H01L 51/56

(52) U.S. Cl. CPC H01L 51/5088; H01L 51/56; H01L 51/5072; H01L 51/5092; H01L 51/5056
USPC 257/40; 438/33

(57) ABSTRACT

An organic light emitting diode display includes a red pixel, a green pixel, and a blue pixel, each pixel including a pixel electrode, a hole supplementary layer on the pixel electrode, a blue organic emission layer on the hole supplementary layer, a first buffer layer on the blue organic emission layer, an electron supplementary layer on the first buffer layer, and a common electrode on the electron supplementary layer, the red pixel and the green pixel further include a red resonance auxiliary layer and a green resonance auxiliary layer respectively on the first buffer layer, a red organic emission layer and a green organic emission layer respectively on the red resonance auxiliary layer and the green resonance auxiliary layer, and a second buffer layer on the red organic emission layer and the green organic emission layer.

### CROSS-REFERENCE TO RELATED APPLICATION

This application claims priority to and the benefit of Korean Patent Application No. 10-2012-0124314 filed in the Korean Intellectual Property Office on Nov. 5, 2012, the entire contents of which are incorporated herein by reference.

### BACKGROUND

1. Field

Embodiments relate to an organic light emitting diode display and a manufacturing method thereof.

2. Description of the Related Art

An organic light emitting diode display includes two electrodes and an organic light emitting member disposed therebetween. Electrons injected from one electrode and holes injected from the other electrode are combined in the organic light emitting member to form excitons. Light is then emitted as the excitons release energy.

### SUMMARY

An exemplary embodiment provides an organic light emitting diode display including a red pixel, a green pixel, and a blue pixel, each pixel including: a pixel electrode; a hole supplementary layer formed on the pixel electrode; a blue organic emission layer formed on the hole supplementary layer; a first buffer layer formed on the blue organic emission layer; an electron supplementary layer formed on the first buffer layer; and a common electrode formed on the electron supplementary layer, wherein the red pixel and the green pixel further include: a red resonance auxiliary layer and a green resonance auxiliary layer respectively formed on the first buffer layer; a red organic emission layer and a green organic emission layer respectively formed on the red resonance auxiliary layer and the green resonance auxiliary layer; and a second buffer layer formed on the red organic emission layer and the green organic emission layer.

According to another exemplary embodiment, the organic light emitting diode display may further include a red interface layer and a green interface layer respectively formed under the red resonance auxiliary layer and the green resonance auxiliary layer.

The red interface layer and the green interface layer may be CGLs (Charge Generated Layers) including HAT-CN (1,4,5,8,9,11-hexaazatriphenylene-hexacarbonitrile).

The hole supplementary layer may include a hole injecting layer formed on the pixel electrode, and a hole transport layer formed on the hole injecting layer, and the electron supplementary layer may include an electron transport layer formed on the first buffer layer, and an electron injecting layer formed on the electron transport layer.

Another exemplary embodiment provides a manufacturing method of an organic light emitting diode display, the method including: forming a thin film transistor, a pixel electrode, and a hole supplementary layer on a substrate; forming a blue organic emission layer on the hole supplementary layer; forming a first buffer layer on the blue organic emission layer; forming a donor film including a base film and a transfer layer; transferring the transfer layer of the donor film onto positions corresponding to a red pixel and a green pixel above the first buffer layer of the substrate; and forming an electron supplementary layer on the entire surfaces of the transfer layer and the first buffer layer, wherein the transfer layer includes: a resonance auxiliary layer transferred onto the positions corresponding to the red pixel and the green pixel; an organic emission layer formed on the resonance auxiliary layer; and a second buffer layer formed on the organic emission layer.

According to another exemplary embodiment, the manufacturing method of the organic light emitting diode display may further include a red interface layer and a green interface layer respectively formed under the red resonance auxiliary layer and the green resonance auxiliary layer corresponding to the red pixel and the green pixel.

The red interface layer and the green interface layer may be CGLs (Charge Generated Layers) including HAT-CN (1,4,5,8,9,11-hexaazatriphenylene-hexacarbonitrile).

The resonance auxiliary layer may include a red resonance auxiliary layer and a green resonance auxiliary layer, and the organic emission layer included in the transfer layer may include a red organic emission layer formed on the red resonance auxiliary layer and a green organic emission layer formed on the green resonance auxiliary layer.

The hole supplementary layer may include: a hole injecting layer formed on the pixel electrode; and a hole transport layer formed on the hole injecting layer, and the electron supplementary layer may include: an electron transport layer formed on the second buffer layer; and an electron injecting layer formed on the electron transport layer.

The blue organic emission layer and the first buffer layer may be formed by vacuum deposition.

### BRIEF DESCRIPTION OF THE DRAWINGS

Features will become apparent to those of skill in the art by describing in detail example embodiments with reference to the attached drawings in which:

FIG. 1 is a top plan view schematically showing the arrangement of pixels of an organic light emitting diode display according to an exemplary embodiment.

FIG. 2 is a cross-sectional view of three pixels, taken along line II-II of the organic light emitting diode display shown in FIG. 1 according to an exemplary embodiment.

FIG. 3 is a cross-sectional view of three pixels of an organic light emitting diode display according to another exemplary embodiment.

FIG. 4 is a view showing the step of transferring a donor film on a second buffer layer for a red pixel according to a manufacturing method of an organic light emitting diode display according to an exemplary embodiment.

FIG. 5 is a view showing the step of transferring a donor film on a second buffer layer for a red pixel according to a manufacturing method of an organic light emitting diode display according to another exemplary embodiment.

FIG. 6 is a graph comparing the blue emission characteristic of an organic light emitting diode display to which a first buffer layer is applied according to an exemplary embodiment with the blue emission characteristic of an organic light emitting diode display to which the first buffer layer is not applied.

### DETAILED DESCRIPTION

Exemplary embodiments will be described more fully hereinafter with reference to the accompanying drawings. As those skilled in the art would realize, the described embodiments may be modified in various different ways, all without departing from the spirit or scope of the embodiments.

A first exemplary embodiment will be representatively described using the same reference numerals for elements having the same configuration in a variety of embodiments, and in the other embodiments, a detailed description of these elements will not be repeated.

It should be noted that the drawings are schematic and not to scale. In the drawings, the dimensions and ratios of the components may be exaggerated or reduced for clarity and convenience. However, such dimensions are only illustrative but not limiting. In the figures, identical and similar structures, elements or parts thereof that appear in two or more figures are generally labeled with the same or similar references in the figures in which they appear. It will be understood that when an element is referred to as being “on” another element, it can be directly on the other element or intervening elements may also be present.

The described embodiments represent concrete examples. Consequently, it will be expected that various modifications of diagrams are possible. Therefore, the embodiments are not limited to specific forms of illustrated regions, and, for example, modifications of the forms due to manufacture may be possible.

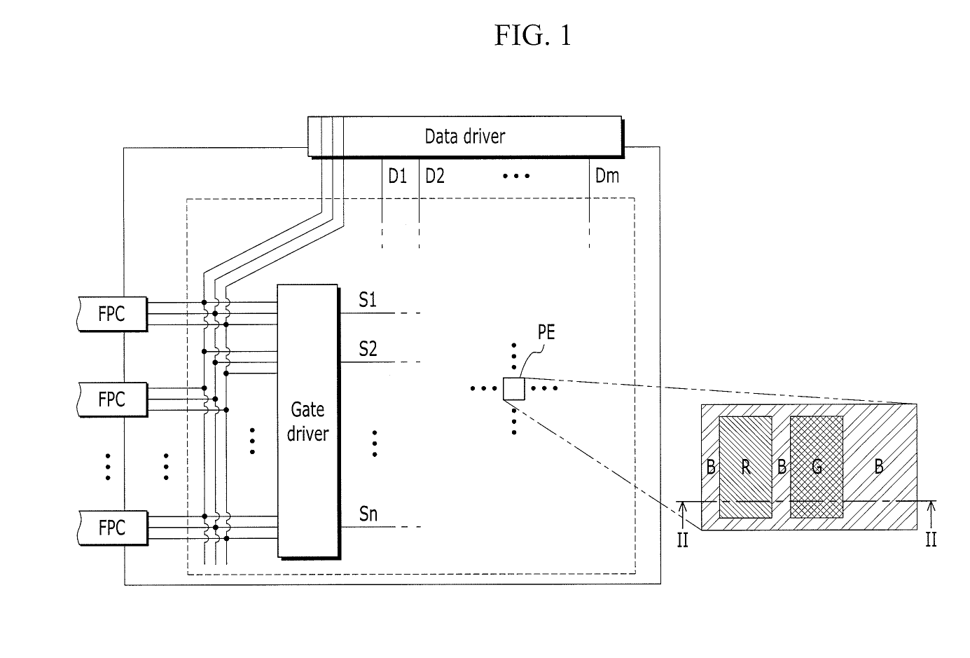

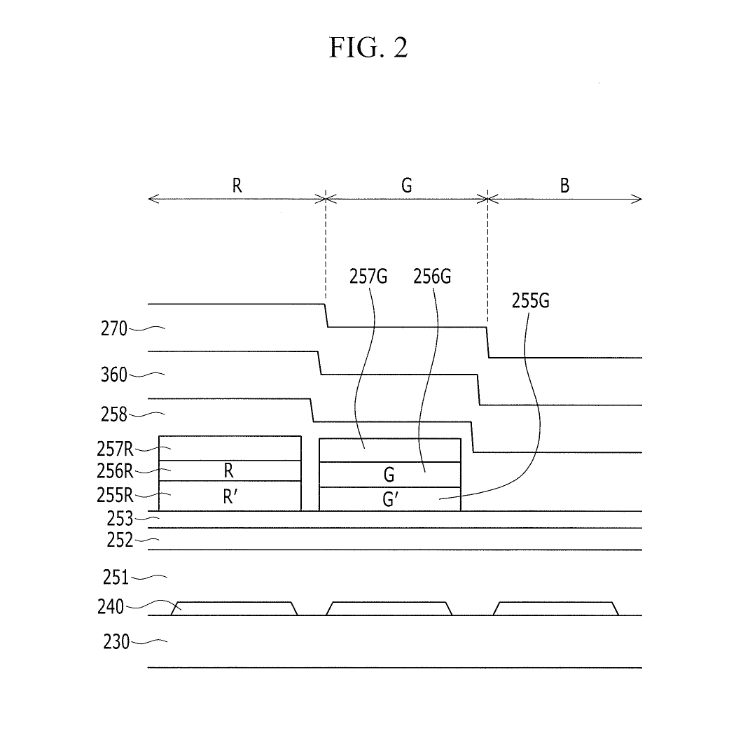

Hereinafter, an organic light emitting diode display according to an exemplary embodiment will be described with reference to FIGS. 1 and 2.

FIG. 1 is a top plan view schematically showing the arrangement of pixels of an organic light emitting diode display according to an exemplary embodiment. As shown in FIG. 1, an organic light emitting diode display according to an exemplary embodiment includes a red pixel R for displaying red, a green pixel G for displaying green, and a blue pixel B for displaying blue. Red, green, and blue are an example of primary colors for full-color displays, and the red pixel R, green pixel G, and blue pixel B may serve as primary pixels for full-color displays. In the present exemplary embodiment, three pixels form one group of pixels and the groups of pixels are repeatedly arranged according to a row and column.

In more detail, regarding the arrangement of the red pixel R, green pixel G, and blue pixel B, a plurality of red pixels R, a plurality of green pixels G, and a plurality of blue pixels are alternately arranged in rows. The areas of the red pixels R and the green pixels G are substantially the same.

The blue pixel B in FIG. 1 is illustrated as surrounding the red pixel R and the green pixel G. This illustrates that a blue organic emission layer is formed over the entire surface, as well as in the blue pixel B. The shape and arrangement of the pixels may be variously changed, and a different pixel such as a white pixel displaying a white color may be further included.

FIG. 2 is a cross-sectional view of three pixels, taken along line II-II of the organic light emitting diode display shown in FIG. 1 according to an exemplary embodiment.

Pixel electrodes 240 corresponding to respective pixels R, G, and B formed on a TFT substrate made of transparent glass, plastic, or the like and having a thin film transistor (TFT). The pixel electrodes 240 may be made of a transparent oxide such as ITO (indium tin oxide) or IZO (indium zinc oxide).

A hole supplementary layer 251 is formed over the entire surfaces of the pixel electrodes 240 in the red, green, and blue pixels R, G, and B. The hole supplementary layer 251 includes a hole injecting layer HIL formed on the pixel electrodes 240 and a hole transport layer HTL formed on the hole injecting layer.

A blue organic emission layer 252 is formed on the hole supplementary layer 251, and a first buffer layer 253 is formed on the blue organic emission layer 252. A red resonance auxiliary layer 255R and a green resonance auxiliary layer 255G are respectively formed on the first buffer layer 253 in the red pixel R and the green pixel R. The thickness of the red resonance auxiliary layer 255R is greater than the thickness of the green resonance auxiliary layer 255G. The red resonance auxiliary layer 255R and the green resonance auxiliary layer 255G are additional layers to adjust resonance distance for each color. They may be made of the same material as the hole transport layer. Although the thickness of the material of the hole transport layer is increased, this does not lead to an increase of the amount of current. Thus, the material of the hole transport layer may be suitable for the material of the resonance auxiliary layer for adjusting resonance distance.

A red organic emission layer 256R is laminated on the red resonance auxiliary layer 256R of the red pixel R, and a green organic emission layer 256G is laminated on the green resonance auxiliary layer 255G of the green pixel G. The red, green and blue organic emission layers 256R, 256G, and 252 may be made of an organic material that emits red, green, and blue light.

An electron supplementary layer 258 is laminated over the entire surfaces of the red and green organic emission layers 256R and 256G and the first buffer layer 253. The electron supplementary layer 258 includes an electron transport layer ETL formed over the entire surfaces of the red and green organic emission layers 256R and 256G and the first buffer layer 253 and an electron injecting layer EIL formed on the electron transport layer.

The hole injecting layer, the hole transport layer, the electron transport layer, and the electron injecting layer may increase the emission efficiency of the organic emission layers. The hole transport layer and the electron transport layer may balance the electrons and holes. The hole injecting layer and the electron injecting layer may enhance the injection of the electrons and holes.

A common electrode 360 transmitting a common voltage is formed on the electron supplementary layer 258. The common electrode 360 may be formed as a dual layer including a lower layer and an upper layer, and has a transflective characteristic that permits light to be partially reflected and partially transmitted. Although the lower layer and the upper layer are all made of a metal having light reflectivity, they may have a transflective characteristic that allows the reflection and transmission of incident light if they are thinned. Also, the, common electrode 360 may be formed as a single layer.

A capping layer (CPL) 270 may be formed on the common electrode 360, and an encapsulation layer (not shown) may be further formed on the capping layer 270. The capping layer 270 may be formed over the entire surface of the common electrode 360 to protect the common electrode 360. The encapsulation layer can protect the organic light emitting element by preventing penetration of moisture or oxygen from the outside.

The organic light emitting diode display emits light toward the common electrode 360, thus displaying an image. The light emitted from the organic emission layers 256R, 256G, and 256B toward the common electrode 360 is partially transmitted through the common electrode 360 and partially reflected toward the pixel electrodes 240. The pixel electrodes 240 reflect the light again and pass it toward the common electrode 360. Accordingly, the light reciprocating between the pixel electrodes 240 and the common electrode 360 generates interference, and the light having a wavelength corresponding to the resonance distance between the pixel electrodes 240 and the common electrode 360 generates constructive interference and thereby the intensity of the corresponding light is enhanced. However the light of the remaining wavelengths generates destructive interference and thereby the intensity of the reflected light is weaker. The reciprocating and interference processes are referred to as a microcavity effect.

Although the above-described exemplary embodiment has been described with respect to a top emission type organic light emitting diode display in which the pixel electrodes 240 have a reflective layer and the common electrode 360 has a transflective characteristic such that light is emitted through the common electrode 360, it is also possible to provide a bottom emission type organic emitting diode display in which the reflective layer of the pixel electrodes 240 is replaced with a transreflective layer and the common electrode 360 is formed with a large thickness to reflect light such that the light is emitted through the substrate 230.

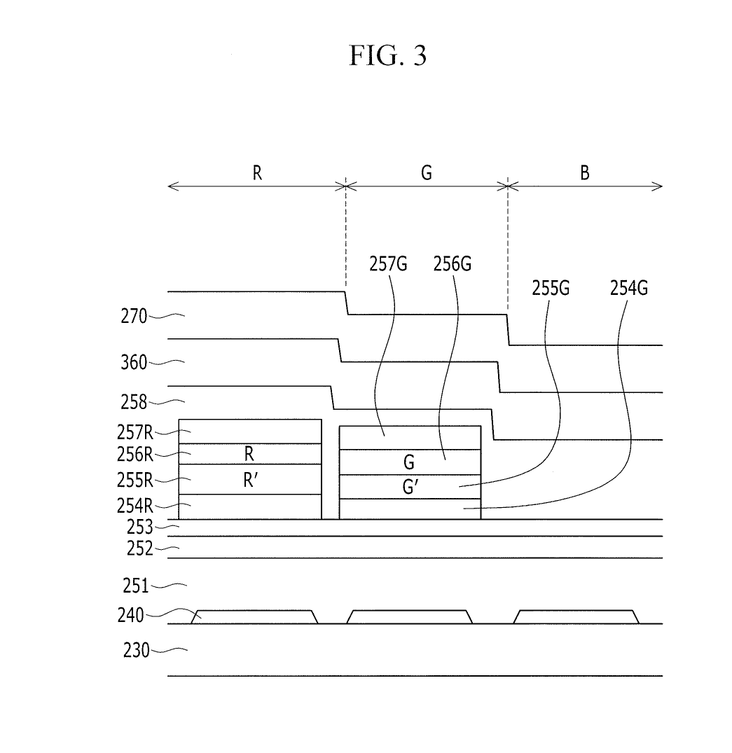

FIG. 3 is a cross-sectional view of three pixels of an organic light emitting diode display according to another exemplary embodiment. An exemplary embodiment shown in FIG. 3 is identical to the structure of the organic light emitting diode display according to the exemplary embodiment shown in FIG. 2, except that a red interface layer 254R is further formed on the first buffer layer 253 of the red pixel R and a green interface layer 254G is further formed on the first buffer layer 253 of the green pixel G.

The red resonance auxiliary layer 255R is formed on the red interface layer 254R, and the green resonance auxiliary layer 255G is formed on the green interface layer 254G. By forming the interface layers 254R and 254G between the resonance auxiliary layers 255R and 255G and the first buffer layer 253, it is possible to minimize thermal damage to the resonance auxiliary layers 255R and 255G and the first buffer layer 253 due to heat energy during a laser thermal transfer process and improve interface characteristics such as the carrier transfer rate of the interface between the resonance auxiliary layers 255R and 255G and the first buffer layer 253.

The red interface layer 254R and the green interface layer 254G may be formed of HAT-CN (1,4,5,8,9,11-hexaazatriphenylene-hexacarbonitrile), which is a hexaazatriphenylene derivative. Also, the red interface layer 254R and the green interface layer 254G may include a material having a melting point of 80 to 170° C. The material having such a melting point includes NPB (N,N-di(naphthalene-1-yl)-N,N-diphenyl-benzidene) and TPA (Triphenylamines).

Hereinafter, a manufacturing method of an organic light emitting diode display according to an exemplary embodiment will be described. First of all, a thin film transistor is formed on a substrate, and then a reflective layer and a conductive oxide member are sequentially laminated thereon and patterned to form pixel electrodes 240.

Next, a hole injecting layer and a hole transport layer are sequentially laminated on the pixel electrodes 240 to form a hole supplementary layer 251.

Next, a blue organic emission layer 252 and a first buffer layer 253 are sequentially laminated on the hole supplementary layer 251. The blue organic emission layer 252 and a first buffer layer 253 may be laminated by vacuum deposition.

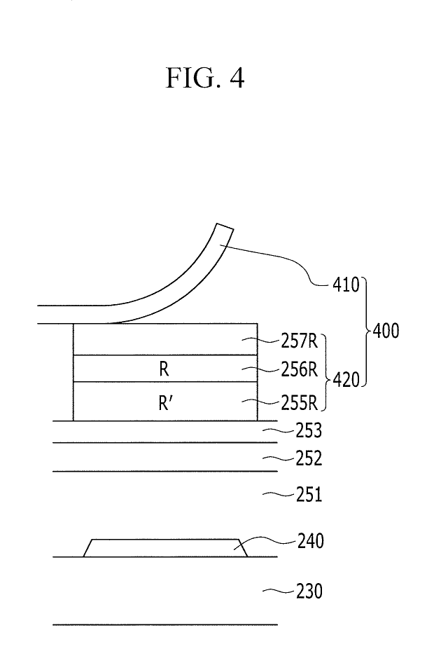

Next, as shown in FIG. 4, a donor film 400 having a red organic emission layer 256R is disposed on the first buffer layer 253. The donor film 400 has a sequentially laminated structure of a base film 410 and a transfer layer 420. The base film 410 may be made of a material which is transparent and has suitable optical properties and sufficient mechanical stability to transfer light to a heat conversion layer. For example, the base film 410 may be made of at least one polymer selected from the group of polyester, polyacryl, polyepoxy, polyethylene, polystyrene, and polyethylene terephthalate, or glass.

A heat conversion layer (not shown) may be formed between the base film 410 and the transfer layer 420. The heat conversion layer is a layer for absorbing light in infrared to visible light region and partially converting the light to heat, should have appropriate optical density, and preferably includes a light-absorbing material for absorbing light. The heat conversion layer may be made of a metal layer formed of Ag, Al, and their oxides and their sulfides, or an organic layer formed of a polymer material including carbon black, graphite or infrared dye.

The transfer layer 420 is a layer that is separated from the base film 410 and transferred to the first buffer layer 253, e.g., by heat energy transferred from the heat conversion layer. A red pixel R has a sequentially laminated structure of a red resonance auxiliary layer 255R, a red organic emission layer 256R, and a second buffer layer 257R.

Then, the first buffer layer 253 comes into uniform contact with the red resonance auxiliary layer 255R of the donor film 400, and a laser is irradiated to the donor film 400 closely contacting the first buffer layer 253 to transfer the transfer layer 420 of the donor film 400 onto the first buffer layer 253. Accordingly, the red resonance auxiliary layer 255R, the red organic emission layer 256R, and the second buffer layer 257R are sequentially formed on the first buffer layer 253.

Next, a green organic emission layer 256G is formed in the same process as above. That is, a donor film having a green organic emission layer 256G is transferred onto the first buffer layer 253 to form a green resonance auxiliary layer 255G, a green organic emission layer 256G, and a second buffer layer 257G on the first buffer layer 253 for a green pixel G.

Next, an electron supplementary layer 258 is formed on the entire surfaces of the second buffer layer 257R and 257G for the red and green pixels R and G and the first buffer layer 253 for a blue pixel B. The electron supplementary layer 258 includes an electron transport layer formed on the second buffer layer 257R and 257G and an electron injecting layer formed on the electron transport layer.

Next, a common electrode 360 and a capping layer 270 are sequentially laminated on the electron supplementary layer 258, and then an encapsulation layer is formed thereon, thereby completing the manufacture of an organic light emitting diode display according to an exemplary embodiment.

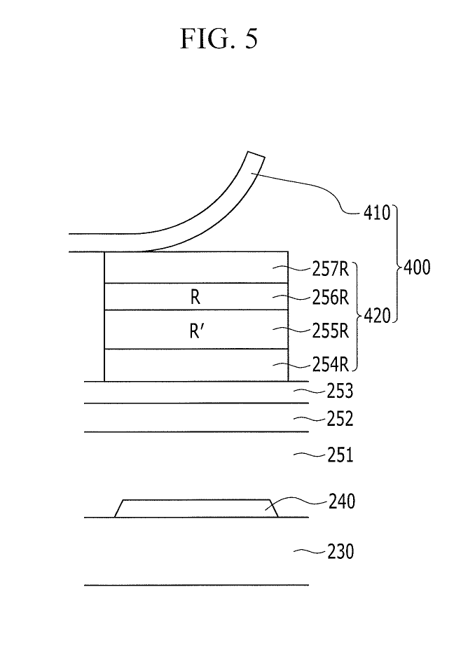

In a manufacturing method of an organic light emitting diode display according to another exemplary embodiment, as shown in FIG. 5, the transfer layer 420 may further include a red interface layer 254R and a green interface layer 254G positioned under the resonance auxiliary layers 255R and 255G at positions corresponding to the red pixel R and the green pixel G. Accordingly, the transfer layer 420 having the red resonance auxiliary layer 255R, red organic emission layer 256R, and second buffer layer 257R sequentially formed on the red interface layer 254R is laminated on the first buffer layer 257R, and a transfer layer having the green resonance auxiliary layer 255G, green organic emission layer 256G, and second buffer layer 257G sequentially laminated on the green interface layer 254G is laminated on the first buffer layer 253.

By forming the interface layers 254R and 254G between the resonance auxiliary layers 255R and 255G and the first buffer layer 253, it is possible to minimize thermal damage to the resonance auxiliary layers 255R and 255G and the first buffer layer 253 due to heat energy during a laser thermal transfer process and improve interface characteristics such as the carrier transfer rate of the interface between the resonance auxiliary layers 255R and 255G and the first buffer layer 253.

The red interface layer 254R and the green interface layer 254G may be formed of HAT-CN (1,4,5,8,9,11-hexaazatriphenylene-hexacarbonitrile), which is a hexaazatriphenylene derivative. Also, the red interface layer 254R and the green interface layer 254G may include a material having a melting point of 80 to 170° C. The material having such a melting point includes NPB (N,N-di(naphthalene-1-yl)-N,N-diphenyl-benzidene) and TPA (Triphenylamines).

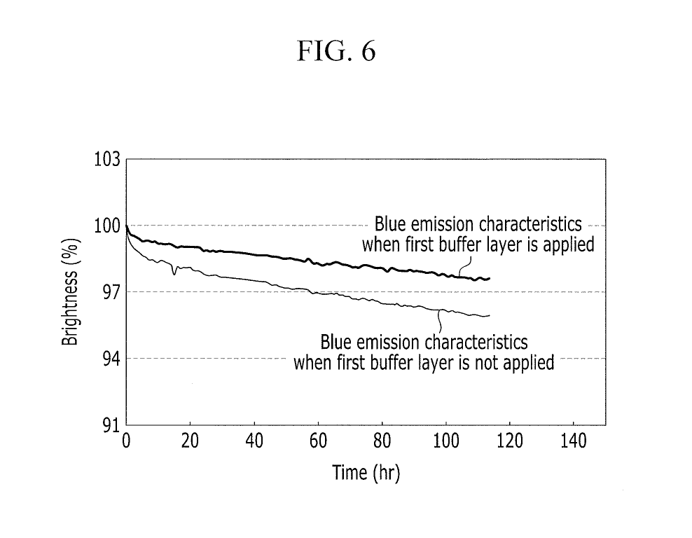

FIG. 6 is a graph comparing the blue emission characteristic of an organic light emitting diode display to which a first buffer layer is applied according to an exemplary embodiment with the blue emission characteristic of an organic light emitting diode display to which the first buffer layer is not applied.

As shown in FIG. 6, it is found that the lifespan of a blue pixel of an organic light emitting diode display to which the first buffer layer is applied according to an exemplary embodiment is lengthened, as compared to when the first buffer layer is not applied. The organic light emitting diode display and manufacturing method thereof according to the exemplary embodiments may substantially prevent the problem of shortened lifespan due to the exposure of a blue organic emission layer during a transfer process under a N2 atmosphere by additionally forming a buffer layer on the blue organic emission layer, and improve light emitting device characteristics by additionally forming a buffer layer suitable for an interface layer during the transfer process. Moreover, transfer characteristics can be controlled by forming a buffer layer having various characteristics on the blue organic emission layer.

By way of summary and review, an example of a method for forming an organic emission layer in an organic light emitting diode display to display full colors includes a Laser Induced Thermal Imaging (LITI). In the LITI method, a laser beam generated from a laser beam generator is patterned using a mask pattern, and the patterned laser beam is irradiated onto a donor film including a base film and a transfer layer to expand part of the transfer layer and transfer it to the organic light emitting diode display, thus forming an organic emission layer on the organic light emitting diode display. Thus, this method has the advantages that each emission layer can be finely patterned and dry etching can be used.

Meanwhile, a BBCL (Bottom Blue Common Layer) structure, a buffer layer is formed on an emission layer in order to substantially prevent damage to the emission layer in a HPS (High Performance Scanning) process. In such a BBCL structure, red and green organic emission layers are transferred and formed directly on a blue organic emission layer by the LITI method. Hence, it is highly likely that the organic emission layers will be damaged. Moreover, there is a possibility that the lifespan of a blue pixel may be degraded as the blue organic emission layer part is exposed when the HPS process is performed in an N2 atmosphere. The organic light emitting diode display according to the embodiments may substantially prevent the problem of shortened lifespan due to the exposure of a blue organic emission layer during a transfer process under a N2 atmosphere

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light emitting diode display, comprising:
a red pixel, a green pixel, and a blue pixel, each pixel including:
a pixel electrode,
a hole supplementary layer on the pixel electrode,
a blue organic emission layer on the hole supplementary layer,
a first buffer layer on the blue organic emission layer,
an electron supplementary layer on the first buffer layer, and
a common electrode on the electron supplementary layer,
wherein the red pixel and the green pixel further include:
a red resonance auxiliary layer and a green resonance auxiliary layer respectively on the first buffer layer,
a red organic emission layer and a green organic emission layer respectively on the red resonance auxiliary layer and the green resonance auxiliary layer, and
a second buffer layer on the red organic emission layer and the green organic emission layer.

2. The organic light emitting diode display of claim 1, further comprising a red interface layer and a green interface layer respectively under the red resonance auxiliary layer and the green resonance auxiliary layer.

3. The organic light emitting diode display of claim 2, wherein the red interface layer and the green interface layer are charge generated layers including 1,4,5,8,9,11-hexaazatriphenylene-hexacarbonitrile.

4. The organic light emitting diode display of claim 1, wherein
the hole supplementary layer includes a hole injecting layer on the pixel electrode, and a hole transport layer on the hole injecting layer, and
the electron supplementary layer includes an electron transport layer on the first buffer layer, and an electron injecting layer on the electron transport layer.

5. A method of manufacturing an organic light emitting diode display, the method comprising:
forming a thin film transistor, a pixel electrode, and a hole supplementary layer on a substrate;
forming a blue organic emission layer on the hole supplementary layer;
forming a first buffer layer on the blue organic emission layer;
forming a donor film including a base film and a transfer layer;
transferring the transfer layer of the donor film onto positions corresponding to a red pixel and a green pixel above the first buffer layer of the substrate; and
forming an electron supplementary layer on entire surfaces of the transfer layer and the first buffer layer,
wherein the transfer layer includes: a resonance auxiliary layer transferred onto the positions corresponding to the red pixel and the green pixel, an organic emission layer formed on the resonance auxiliary layer, and a second buffer layer formed on the organic emission layer.

6. The method of claim 5, wherein the resonance auxiliary layer includes a red resonance auxiliary layer corresponding to the red pixel and a green resonance auxiliary layer corresponding to the green pixel, and the method further comprises forming a red interface layer and a green interface layer respectively under the red resonance auxiliary layer and the green resonance auxiliary layer.

7. The method of claim 6, wherein the red interface layer and the green interface layer are charge generated layers including 1,4,5,8,9,11-hexaazatriphenylene-hexacarbonitrile.

8. The method of claim 5, wherein:
the resonance auxiliary layer included in the transfer layer includes a red resonance auxiliary layer and a green resonance auxiliary layer, and
the organic emission layer included in the transfer layer includes a red organic emission layer formed on the red resonance auxiliary layer and a green organic emission layer formed on the green resonance auxiliary layer.

9. The method of claim 5, wherein:
forming the hole supplementary layer includes forming a hole injecting layer on the pixel electrode, and forming a hole transport layer on the hole injecting layer, and
forming the electron supplementary layer includes forming an electron transport layer on the second buffer layer, and forming an electron injecting layer on the electron transport layer.

10. The method of claim 5, wherein the blue organic emission layer and the first buffer layer are formed by vacuum deposition.
